(19) United States
(12) Patent Application Publication
(10) Pub. No.: US 2012/0270355 A1
(43) Pub. Date: Oct. 25, 2012

(54) INERTIAL SENSOR AND METHOD OF MANUFACTURING THE SAME

(75) Inventors: Won Kyu JEUNG, Seoul (KR); Jong Woon KIM, Seoul (KR)

(73) Assignee: SAMSUNG ELECTRO-MECHANICS CO., LTD., Gyunggi-do (KR)

(21) Appl. No.: 13/536,842

(22) Filed: Jun. 28, 2012

Related U.S. Application Data
(62) Division of application No. 12/716,140, filed on Mar. 2, 2010.

(30) Foreign Application Priority Data
Dec. 22, 2009 (KR) 10-2009-0129076

(51) Int. Cl. H01L 21/02

(52) U.S. Cl. 438/53; 257/E21.002

(57) ABSTRACT

Disclosed herein is an inertial sensor, which includes a diaphragm having a piezoelectric element or a piezoresistive element formed on one surface thereof, a mass element integrated with the center of the other surface of the diaphragm in which the distal end of the mass element has a larger width than the width of the proximal end in contact with the diaphragm, and a supporter formed along the edge of the other surface of the diaphragm, so that the use of the mass element having the above shape results in decreased spring constant and increased distance from the center of the diaphragm to the center of the mass element, thereby simultaneously realizing a reduction in the size of the inertial sensor and an increase in performance thereof. A method of manufacturing the inertial sensor is also provided.

### CROSS REFERENCE TO RELATED APPLICATION

This application is a divisional of co-pending U.S. patent application Ser. No. 12/716,140, filed Mar. 2, 2012 which claims the benefit of Korean Patent Application No. 10-2009-0129076, filed Dec. 22, 2009, entitled “Inertial sensor and producing method thereof”, which is hereby incorporated by reference in its entirety into this application.

### BACKGROUND OF THE INVENTION

1. Technical Field

The present invention relates to an inertial sensor and a method of manufacturing the same.

2. Description of the Related Art

Recently, an inertial sensor is being used not only for artificial satellites and munitions including missiles, pilotless airplanes and so on but also for vehicles including air bags, electronic stability control (ESC) systems, black boxes and so on, anti-shake camcorders, motion sensing mobile phones or game machines, and navigation systems.

Inertial sensors are divided into acceleration sensors for measuring linear motion and angular velocity sensors for measuring rotational motion. The acceleration may be determined by the equation F=ma which is Newton's law of motion in which m is the mass of a moving object and a is the acceleration which is intended to be measured. The angular velocity may be determined by the equation F=2 mΩ·v for the Coriolis force in which m is the mass of a moving object, Q is the angular velocity which is intended to be measured, and v is the velocity. The direction of the Coriolis force is determined by the axis of velocity (v) and the rotational axis of angular velocity (Q).

Inertial sensors are divided into ceramic sensors and microelectromechanical system (MEMS) sensors depending on the manufacturing process. Furthermore, MEMS sensors are classified into the capacitive type, the piezoresistive type, and the piezoelectric type, depending on the principle behind the sensing.

In order to apply the inertial sensor to various fields, the inertial sensor is required to be reduced in size and be increased in performance. To satisfy such requirements, a variety of methods for decreasing a spring constant and increasing the distance from the center of a diaphragm to the center of a mass element are devised. However, an inertial sensor which to is reduced in size and increased in performance at the same time has not yet been developed.

### SUMMARY OF THE INVENTION

Accordingly, the present invention has been made keeping in mind the problems encountered in the related art and the present invention is intended to provide an inertial sensor which includes a mass element formed such that the distal portion thereof has a larger width than the width of the proximal portion in contact with a diaphragm, so that a spring constant is decreased and the distance from the center of the diaphragm to the center of the mass element is increased, thus achieving high performance sensitivity, and also to provide a method of manufacturing the same.

An aspect of the present invention provides an inertial sensor, including a diaphragm having a piezoelectric element or a piezoresistive element formed on one surface thereof, a mass element integrated with the center of the other surface of the diaphragm in which the distal end of the mass element has a larger width than the width of the proximal end in contact with the diaphragm, and a supporter formed along the edge of the other surface of the diaphragm.

In this aspect, the width of the mass element may increase from the proximal end in contact with the diaphragm toward the distal end opposite the proximal end in contact with the diaphragm.

In this aspect, the mass element may include a connector in contact with the diaphragm and a main body having a predetermined width larger than the width of the connector and extending so as to be stepped from the connector.

As such, the predetermined width of the main body may be uniform. Alternatively, the predetermined width of the main body may increase from a proximal end adjacent to the connector toward a distal end opposite the proximal end.

In this aspect, the supporter may be integrated with the diaphragm.

Another aspect of the present invention provides a method of manufacturing the inertial sensor, including (A) forming a piezoelectric element or a piezoresistive element on one surface of a diaphragm, and forming a silicon layer on the other surface of the diaphragm, (B) applying a photoresist on the silicon layer, and patterning the photoresist so as to form an open portion at the region of the silicon layer other than the center of the silicon layer and the edge of the silicon layer, and (C) selectively removing the region of the silicon layer at which the open portion has been formed using etching, thus forming a mass element at the center of the silicon layer and a supporter along the edge of the silicon layer.

In this aspect, in (C) the mass element may be formed such that the distal end of the mass element has a larger width than the width of the proximal end in contact with the diaphragm.

In this aspect, the width of the mass element may increase from the proximal end in contact with the diaphragm toward the distal end opposite the proximal end in contact with the diaphragm.

In this aspect, the mass element may include a connector in contact with the diaphragm and a main body having a predetermined width larger than the width of the connector and extending so as to be stepped from the connector.

As such, the predetermined width of the main body may be uniform.

Alternatively, the predetermined width of the main body may increase from a proximal end adjacent to the connector toward a distal end opposite the proximal end.

In this aspect, in (C) the etching may be anisotropic etching or isotropic etching.

### BRIEF DESCRIPTION OF THE DRAWINGS

The features and advantages of the present invention will be more clearly understood from the following detailed description taken in conjunction with the accompanying drawings, in which:

FIG. 1 is a cross-sectional view showing an inertial sensor according to a first embodiment of the present invention;

FIG. 2 is a cross-sectional view showing an inertial sensor according to a fourth embodiment embodiment of the present invention;

FIG. 3 is a cross-sectional view showing an inertial sensor according to a second embodiment of the present invention;

FIG. 4 is a cross-sectional view showing an inertial sensor according to a third embodiment of the present invention; and

FIGS. 5 to 8 are views sequentially showing a process of manufacturing the inertial sensor according to the embodiment of the present invention.

### DESCRIPTION OF SPECIFIC EMBODIMENTS

Hereinafter, embodiments of the present invention will be described in detail while referring to the accompanying drawings. Throughout the drawings, the same reference numerals are used to refer to the same or similar elements. In the description, the terms “first”, “second” and so on are used to distinguish one element from another element, and the elements are not defined by the above terms. Moreover, descriptions of known techniques, even if they are pertinent to the present invention, are regarded as unnecessary and may be omitted when they would make the characteristics of the invention and the description unclear.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying to out the invention.

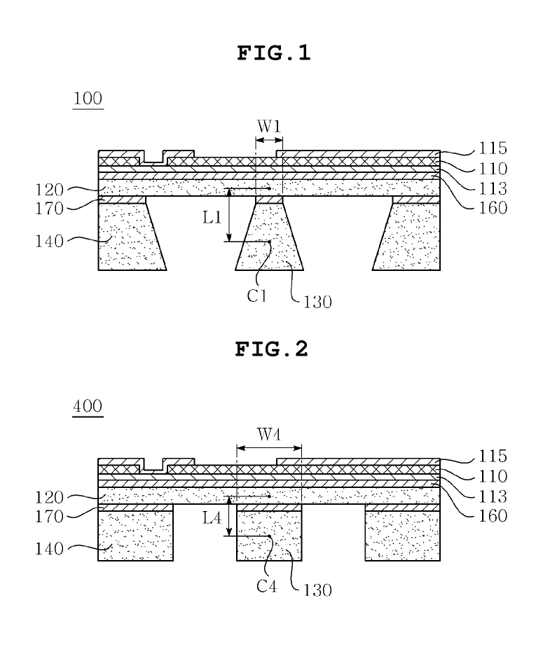

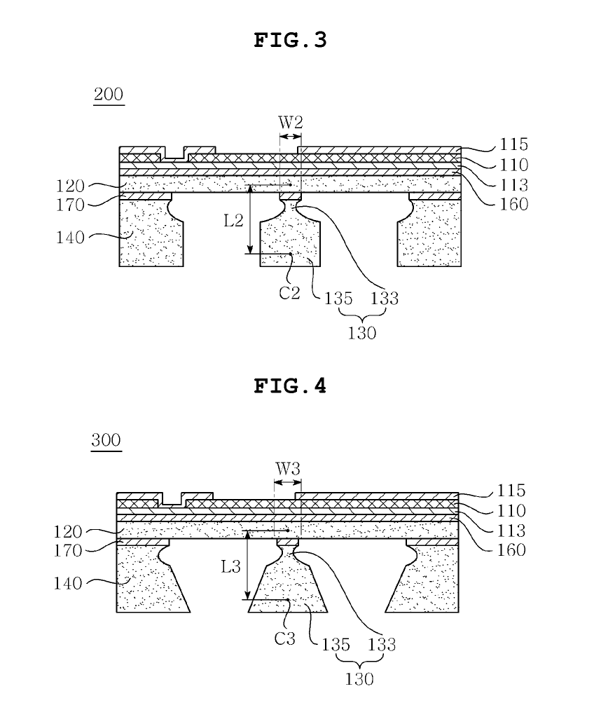

FIG. 1 is a cross-sectional view showing an inertial sensor according to a first embodiment of the present invention, and FIG. 2 is a cross-sectional view showing an inertial sensor according to a fourth embodiment embodiment of the present invention.

As shown in FIG. 1, the inertial sensor 100 according to the present embodiment includes a diaphragm 120 having a piezoelectric element or piezoresistive element 110 formed on one surface thereof, a mass element 130 integrated with the center of the other surface of the diaphragm 120 in which the distal end of the mass element 130 has a larger width than the width of the proximal end in contact with the diaphragm 120, and a supporter 140 formed along the edge of the other surface of the diaphragm 120.

The piezoelectric element or piezoresistive element 110 functions to sense elastic deformation of the diaphragm 120 to measure the acceleration, and is formed on one surface of the diaphragm 120. Furthermore, the piezoelectric element 110 generates electrical signals depending on the elastic deformation of the diaphragm 120, and resistance of the piezoresistive element 110 changes depending on the elastic deformation of the diaphragm 120. In order to measure the changes in electrical signals of the piezoelectric element 110 or in resistance of the piezoresistive element 110, a first electrode 113 and a second electrode 115 may be formed on both surfaces of the piezoelectric element or piezoresistive element 110. As such, the first electrode 113 and the second electrode 115 may be formed using a plating process or a deposition process. Further, an insulating layer 160 may be disposed between the diaphragm 120 and the first electrode 113. The configuration of the inertial sensor of FIG. 1 is illustrative, and the piezoelectric element or piezoresistive element 110, the electrodes 113, 115 and the insulating layer 160 may be of various configurations.

The diaphragm 120 functions as a spring which undergoes elastically deformation in relation to the motion of the mass element 130 formed at the center thereof, and is supported by the supporter 140 formed along the edge thereof. As such, though the material to of the diaphragm 120 is not particularly limited, the diaphragm 120 may be formed using an SOI wafer.

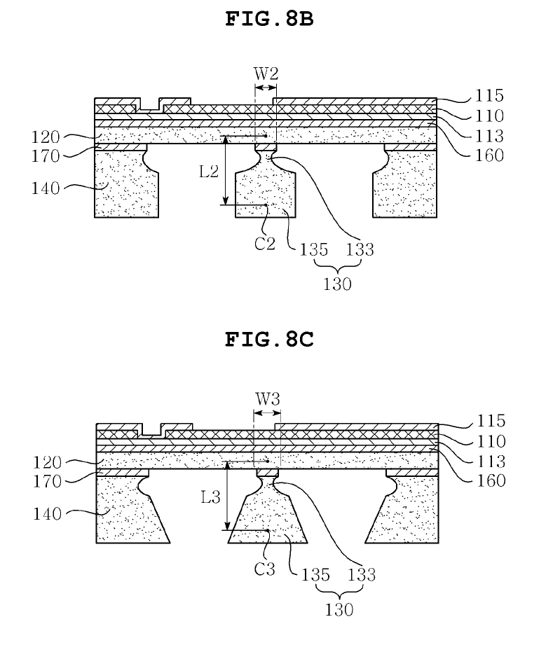

The mass element 130 functions to cause displacement depending on the acceleration thereby elastically deforming the diaphragm 120, and is formed at the center of the other surface of the diaphragm 120. In particular, because the mass element 130 according to the present invention is integrated with the diaphragm 120, an additional process of processing a mass element or of boding a mass element to a diaphragm may be omitted. As shown in the drawing, an insulating layer 170 is disposed between the mass element 130 and the diaphragm 120 but is regarded as an insulating layer of the SOI wafer, and the mass element 130 and the diaphragm 120 are original constituents of the SOI wafer, and therefore, the mass element 130 and the diaphragm 120 are integrated with each other (FIGS. 5 to 8).

Furthermore, compared to the proximal end of the mass element 130 in contact with the diaphragm 120, the distal end thereof is wider. In particular, it is desirable that the mass element 130 have a width increasing from the proximal end thereof toward the distal end opposite the proximal end thereof. When the mass element 130 is manufactured to have the above shape, the output of torsional mode and translation mode is increased thus ensuring high performance sensitivity, which is specified below with reference to the fourth embodiment embodiment of FIG. 2 (herein, the mass element 130 according to the fourth embodiment embodiment and the mass element 130 according to the present embodiment have the same volume and mass).

When comparing the center C1 of gravity of the mass element 130 according to the present embodiment with the center C4 of gravity of the mass element 130 according to the fourth embodiment embodiment, the distance from the center of gravity to the diaphragm 120 can be seen to increase (L4→L1). Thus, the moment is increased, and the angular displacement is increased, ultimately raising the output of torsional mode.

Also, the width W1 of the proximal end of the mass element 130 according to the present embodiment is narrower than the width W4 of the proximal end of the mass element 130 according to the fourth embodiment embodiment. Thus, as the width of the diaphragm 120 integrated with the mass element 130 is also decreased, the actual length of the diaphragm 120 which is responsible for the functioning thereof becomes lengthened. Thereby, the spring constant of the diaphragm 120 is decreased and the linear displacement is increased, ultimately increasing the output of translation mode.

Though the process of manufacturing the mass element 130 having the above shape is not particularly limited, it may include anisotropic etching, isotropic etching or a combination of isotropic etching and anisotropic etching. Also, the material of the mass element 130 is not particularly limited, and may include silicon like the diaphragm 120.

The supporter 140 functions to support the diaphragm 120 to thus ensure enough space to be able to cause the displacement of the mass element 130, and is formed along the edge of the other surface of the diaphragm 120. As such, the supporter 140 may be integrated with the diaphragm 120, so that an additional process of processing a supporter 140 or bonding a supporter 140 to a diaphragm 120 is omitted. The material of the supporter 140 is not particularly limited, and may include silicon like the mass element 130.

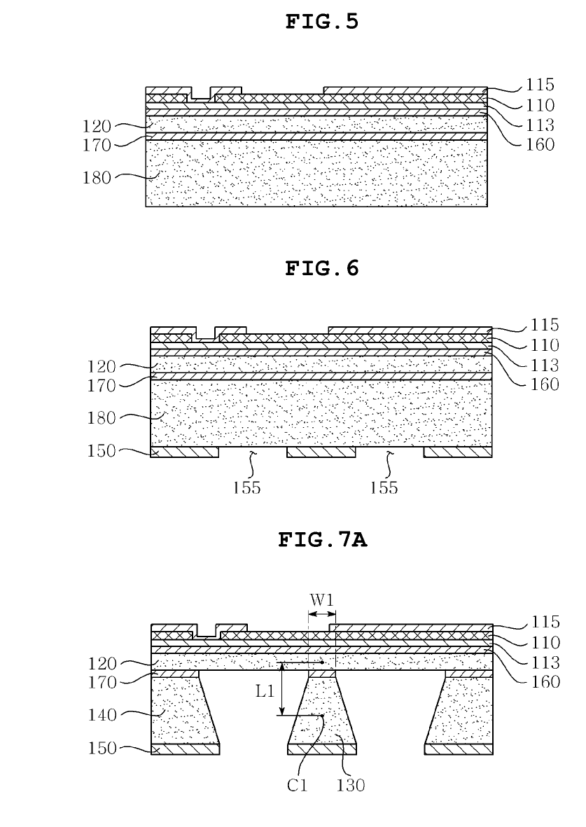

FIG. 3 is a cross-sectional view showing an inertial sensor according to a second embodiment of the present invention.

As shown in FIG. 3, the inertial sensor 200 according to the present embodiment is apparently different in terms of the shape of a mass element 130 from the inertial sensor 100 according to the first embodiment. Thus, in the present embodiment, the shape of the mass element 130 will be mainly described, and the description which overlaps with that of the first embodiment will be omitted.

The mass element 130 according to the present embodiment includes a connector 133 in contact with the diaphragm 120 and a main body 135 having a predetermined width larger than the width of the connector 133 and extending so as to be stepped from the connector 133. Because the connector 133 having a width narrower than that of the main body 135 is provided, when comparing the center C2 of gravity of the mass element 130 according to the present embodiment with the center C4 of gravity of the mass element 130 according to the fourth embodiment embodiment, the distance from the center of gravity to the diaphragm 120 can be seen to increase (L4→L2). Hence, the moment is increased and the angular displacement is increased, ultimately raising the output of torsional mode.

Also, when the connector 133 is used, the width W2 of the connector 133 according to the present embodiment is narrower than the width W4 of the proximal end of the mass element 130 according to the fourth embodiment embodiment or the width W1 of the proximal end of the mass element 130 according to the first embodiment. Thus, as the width of the diaphragm 120 integrated with the mass element 130 is also decreased, the actual length of the diaphragm 120 which is responsible for the functioning thereof becomes lengthened. Hence, the spring constant of the diaphragm 120 is decreased and the linear displacement is increased, ultimately raising the output of translation mode.

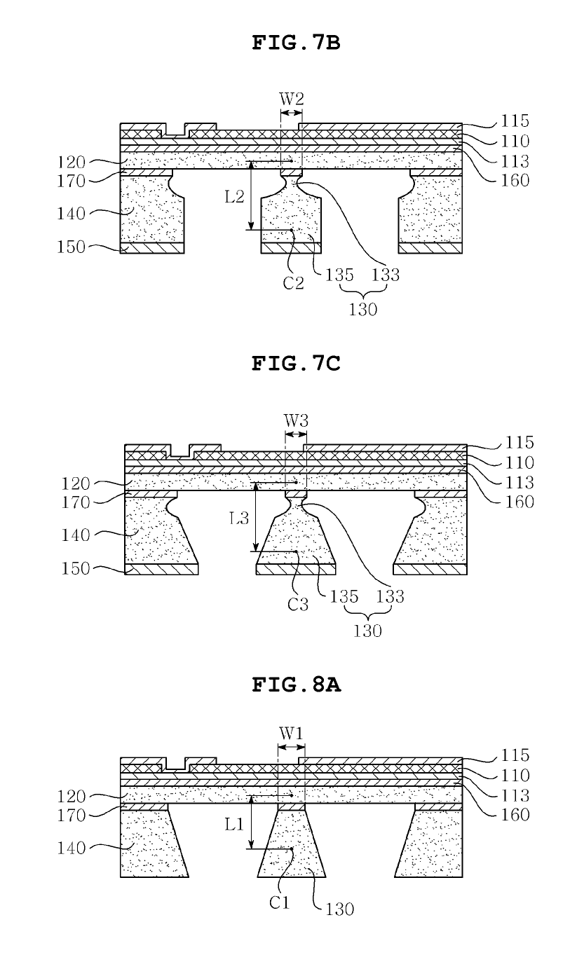

FIG. 4 is a cross-sectional view showing an inertial sensor according to a third embodiment of the present invention.

As shown in FIG. 4, the inertial sensor 300 according to the present embodiment is quite different in terms of the shape of the mass element 130 from the inertial sensors 100, 200 according to the first and second embodiments. In particular, the shape of the mass element 130 according to the present embodiment includes a combination of the shape of the mass element 130 according to the first embodiment and the shape of the mass element 130 according to the second embodiment. What is mainly described below is the shape of the mass element 130.

The mass element 130 according to the present embodiment includes a connector 133 in contact with the diaphragm 120 and a main body 135 having a predetermined width larger than the width of the connector 133 and extending so as to be stepped from the connector 133, in which the predetermined width of the main body 135 increases from a proximal end adjacent to the connector toward a distal end opposite the proximal end. Thus, when comparing the center C3 of gravity of the mass element 130 according to the present embodiment with the center C4 of gravity of the mass element 130 according to the fourth embodiment embodiment, the center C1 of gravity of the mass element 130 according to the first embodiment and the center C2 of gravity of the mass element 130 according to the second embodiment, the distance from the center of gravity to the diaphragm 120 can be seen to increase (L1,L2,L4→L3). Thus, the moment is further increased and the angular displacement is increased, ultimately raising the output of torsional mode.

Also, because the width W3 of the connector 133 according to the present embodiment is the same as the width W2 of the connector 133 according to the second embodiment, it is narrower than the width W4 of the proximal end of the mass element 130 according to the fourth embodiment embodiment or the width W1 of the proximal end of the mass element 130 according to the first embodiment. Thus, as the width of the diaphragm 120 integrated with the mass element 130 is also decreased, the actual length of the diaphragm 120 which is responsible for the functioning thereof becomes lengthened. Hence, the spring constant of the diaphragm 120 is decreased and the linear displacement is increased, ultimately raising the output of translation mode.

FIGS. 5 to 8 sequentially show a process of manufacturing the inertial sensor according to the embodiment of the present invention.

As shown in FIGS. 5 to 8, the method of manufacturing the inertial sensor according to the present embodiment includes (A) forming a piezoelectric element or piezoresistive element 110 on one surface of a diaphragm 120 and forming a silicon layer 180 on the other surface of the diaphragm 120, (B) applying a photoresist 150 on the silicon layer 180 and patterning the photoresist 150 so as to form an open portion 155 at the region of the silicon layer 180 other than the center of the silicon layer 180 and the edge of the silicon layer 180, and (C) selectively removing the region of the silicon layer 180 at which the open portion 155 has been formed using etching thus forming a mass element 130 at the center of the silicon layer 180 and forming a supporter 140 along the edge of the silicon layer 180.

As shown in FIG. 5, the piezoelectric element or piezoresistive element 110 and the silicon layer 180 are formed on the diaphragm 120. As such, because the piezoelectric element or piezoresistive element 110 functions to sense elastic deformation of the diaphragm 120, a first electrode 113 and a second electrode may be formed on both surfaces of the piezoelectric element or piezoresistive element 110, and furthermore, an insulating layer 160 may be formed between the diaphragm 120 and the first electrode 113. This configuration is merely illustrative, and the piezoelectric element or piezoresistive element 110, the electrodes 113, 115 and the insulating layer 160 may be of various configurations. In the formation of the silicon layer 180 on the other surface of the diaphragm 120, the additional silicon layer 180 need not be essentially formed on the other surface of the diaphragm 120. Alternatively, an SOI wafer may be prepared, the upper layer 120 of which may be used as the diaphragm 120 and the lower layer 180 of which may be used as the silicon layer 180. As such, an insulating layer 170 of the SOI wafer may be disposed between the upper layer 120 and the lower layer 180.

Next, as shown in FIG. 6, the photoresist 150 is applied on the silicon layer 180 and then patterned so as to form the open portion 155 at the region of the silicon layer 180 other than the center of the silicon layer 180 and the edge thereof. Specifically, the photoresist 150 may be patterned by closely attaching an artwork film to a dry film, radiating UV light so as to selectively cure only a portion of the photoresist 150 applied on the center and edge of the silicon layer 180, and removing the other portion thereof using a developing solution. This procedure is carried out in order to form the mass element 130 and the supporter 140 using selective etching in a subsequent procedure.

Next, as shown in FIGS. 7A, 7B and 7C, the mass element 130 and the supporter 140 are formed by etching. Because the open portion 155 is formed at the region of the silicon layer 180 other than the center of the silicon layer 180 and the edge thereof in the previous procedure, only the region of the silicon layer 180 at which the open portion 155 has been formed is selectively removed using etching, so that the mass element 130 is formed at the center of the silicon layer 180 and the supporter 140 is formed along the edge of the silicon layer 180. On the other hand, in the case of an SOI wafer being prepared so that the upper layer 120 thereof is used as the diaphragm 120 and the lower layer 180 thereof is used as the silicon layer 180, the mass element 130 and the supporter 140 formed in this procedure are integrated with the diaphragm 120, thus omitting an additional process of forming the mass element 130 and the supporter 140 or bonding the mass element 130 and the supporter 140 to the diaphragm 120.

Furthermore, in this procedure, the silicon layer 180 is selectively removed using anisotropic etching, isotropic etching, or a combination of anisotropic etching and isotropic etching, thereby enabling the mass element 130 to be formed into a variety of shapes. Because the mass element 130 is formed such that the distal end thereof has a larger width than the width of the proximal end in contact with the diaphragm 120, the output of torsional mode and translation mode may be raised as mentioned above. Specifically, the mass element 130 may be manufactured to have a width increasing from the proximal end in contact with the diaphragm 120 toward the distal end opposite the proximal end (FIG. 7A), to include a connector 133 in contact with the diaphragm 120 and a main body 135 having a predetermined width larger than the width of the connector 133 and extending so as to be stepped from the connector 133 (FIG. 7B), or to include a connector 133 in contact with the diaphragm 120 and a main body 135 having a predetermined width larger than the width of the connector 133 and extending so as to be stepped from the connector 133 in which the predetermined width of the main body 135 increases from a proximal end adjacent to the connector 133 toward a distal end opposite the proximal end (FIG. 7C).

Next, as shown in FIGS. 8A, 8B and 8C, the photoresist 150 is removed. Because the etching process has terminated, the photoresist 150 is removed using a stripping solution. Thereby, the manufacturing process of the inertial sensor according to the present to embodiment may be completed.

As described hereinbefore, the present invention provides an inertial sensor and a method of manufacturing the same. According to the present invention, a mass element is formed such that a distal portion thereof has a larger width than the width of a proximal portion in contact with a diaphragm, thus decreasing a spring constant and increasing the distance from the center of the diaphragm to the center of the mass element, thereby simultaneously realizing a reduction in the size of the inertial sensor and an increase in performance thereof.

Also, according to the present invention, the mass element is manufactured to be integrated with the diaphragm, thus omitting a process of bonding the mass element to the diaphragm, thereby simplifying the manufacturing process of the inertial sensor.

Although the embodiments of the present invention regarding the inertial sensor and the method of manufacturing the same have been disclosed for illustrative purposes, those skilled in the art will appreciate that a variety of different modifications, additions and substitutions are possible, without departing from the scope and spirit of the invention as disclosed in the accompanying claims. Accordingly, such modifications, additions and substitutions should also be understood as falling within the scope of the present invention.

What is claimed is:

1. A method of manufacturing an inertial sensor, comprising:
(A) forming a piezoelectric element or a piezoresistive element on one surface of a diaphragm, and forming a silicon layer on the other surface of the diaphragm;
(B) applying a photoresist on the silicon layer, and patterning the photoresist so as to form an open portion at a region of the silicon layer other than a center of the silicon layer and an edge of the silicon layer; and
(C) selectively removing the region of the silicon layer at which the open portion to has been formed using etching, thus forming a mass element at the center of the silicon layer and a supporter along the edge of the silicon layer.

2. The method as set forth in claim 1, wherein in (C) the mass element is formed such that a distal end of the mass element has a larger width than a width of a proximal end in contact with the diaphragm.

3. The method as set forth in claim 2, wherein the width of the mass element increases from the proximal end in contact with the diaphragm toward the distal end opposite the proximal end in contact with the diaphragm.

4. The method as set forth in claim 2, wherein the mass element comprises:
a connector in contact with the diaphragm; and
a main body having a predetermined width larger than a width of the connector and extending so as to be stepped from the connector.

5. The method as set forth in claim 4, wherein the predetermined width of the main body is uniform.

6. The method as set forth in claim 4, wherein the predetermined width of the main body increases from a proximal end adjacent to the connector toward a distal end opposite the proximal end.

7. The method as set forth in claim 1, wherein in (C) the etching is anisotropic etching or isotropic etching.
